(19) United States
(12) Patent Application Publication
(10) Pub. No.: US 2018/0240827 A1
(43) Pub. Date: Aug. 23, 2018

(54) PACKAGE STRUCTURE AND PACKAGING METHOD

(71) Applicant: China Wafer Level CSP Co., Ltd., Suzhou, Jiangsu (CN)

(72) Inventors: Zhiqi Wang, Suzhou, Jiangsu Province (CN); Fangyuan Hong, Suzhou, Jiangsu (CN)

(73) Assignee: China Wafer Level CSP Co., Ltd., Suzhou, Jiangsu (CN)

(21) Appl. No.: 15/752,887

(22) PCT Filed: Sep. 1, 2016
(86) PCT No.: PCT/CN2016/097797

§ 371 Date: Feb. 14, 2018

(30) Foreign Application Priority Data
Sep. 2, 2015 (CN) 201510552405.0
Sep. 2, 2015 (CN) 201520673688.X

(51) Int. Cl. H01L 27/146

(52) U.S. Cl. CPC H01L 27/14618; H01L 27/14625; H01L 27/14683

(57) ABSTRACT

A packaging structure and a packaging method are provided. The packaging structure includes: a chip unit, where a first surface of the chip unit includes a sensing region; and an upper cover plate, where a first surface of the upper cover plate is provided with a support structure, the upper cover plate covers the first surface of the chip unit, the support structure is located between the upper cover plate and the chip unit, the sensing region is located in a cavity enclosed by the support structure and the first surface of the chip unit, and the upper cover plate has a preset thickness, so that light reflected by a sidewall of the upper cover plate is not directly incident on the sensing region.

This application claims the priority to Chinese Patent Application No. 201510552405.0, titled “ PACKAGE STRUCTURE AND PACKAGING METHOD”, filed on Sep. 02, 2015 with the State Intellectual Property Office of People's Republic of China, and the priority to Chinese Patent Application No. 201520673688.X, titled “PACKAGE STRUCTURE”, filed on Sep. 02, 2015 with the State Intellectual Property Office of People's Republic of China, which are incorporated herein by reference in their entireties.

### FIELD

The present disclosure relates to the technical field of semiconductors, and in particular to a packaging structure and a packaging method.

### BACKGROUND

In the conventional technology, an IC chip is connected with an external circuit by metal wire bonding. With reduction in feature sizes of IC chips and an expansion of scales of integrated circuits, the wire bonding technology is no longer suitable.

The wafer level chip size packaging (WLCSP) technology is a technology of packaging and testing a whole wafer and then cutting the whole wafer to acquire single finished chips, where the size of the packaged chip is the same as the size of a bare chip. The wafer level chip size packaging technology overturns the traditional packaging manners such as the ceramic leadless chip carrier packaging manner and the organic leadless chip carrier packaging manner, and meets market requirements for microelectronic products which are increasingly lighter, smaller, shorter, thinner and cheaper. A chip packaged with the wafer level chip size packaging technology is highly miniaturized, and the cost of the chip is greatly reduced with reduction of the size of the chip and an increase in the size of the wafer. The wafer level chip size packaging technology integrates IC design, wafer fabrication, and package test, and is a focus and a development trend of the current field of packaging.

An image sensor chip includes a sensing region, and is capable of converting an optical image into an electronic signal. In a case where the image sensor chip is packaged using the existing wafer level chip size packaging technology, an upper cover substrate is generally formed on the sensing region for protecting the sensing region from being damaged or contaminated during a packaging process. The upper cover substrate may be retained after the wafer level chip size packaging process is finished for continuing protecting the sensing region from being damaged or contaminated during use of the image sensor chip.

However, the image sensor formed by the above wafer level chip size packaging technology exhibits poor performance.

### SUMMARY

An issue addressed by the present disclosure is that an image sensor formed by the conventional technology exhibits poor performance.

To address the above issue, a packaging structure is provided according to an embodiment of the present disclosure, which includes: a chip unit, where a first surface of the chip unit includes a sensing region; and an upper cover plate, where a first surface of the upper cover plate is provided with a support structure, the upper cover plate covers the first surface of the chip unit, the support structure is located between the upper cover plate and the chip unit, the sensing region is located in a cavity enclosed by the support structure and the first surface of the chip unit, and the upper cover plate has a preset thickness, so that light reflected by a sidewall of the upper cover plate is not directly incident on the sensing region.

Optionally, the preset thickness may range from 50 μm to 200 μm.

Optionally, the preset thickness may be 100 μm.

Optionally, the preset thickness may be determined based on a width of the sensing region, a width of the support structure, and a height of the support structure.

Optionally, a ratio of the preset thickness to the width of the support structure may be smaller than a ratio of the height of the support structure to the width of the sensing region.

Optionally, a material of the upper cover plate may be a transparent material.

Optionally, the chip unit may further include: a contact pad located outside the sensing region; a through hole extending through the chip unit from a second surface of the chip unit opposite to the first surface of the chip unit, where the contact pad is exposed through the through hole; an insulation layer covering the second surface of the chip unit and a surface of a sidewall of the through hole; a metal layer located on a surface of the insulation layer and electrically connected to the contact pad; a solder mask located on a surface of the metal layer and the surface of the insulation layer, where the solder mask is provided with an opening through which a portion of the metal layer is exposed; and a protrusion for external connection by which the opening is filled, where the protrusion for external connection is exposed outside a surface of the solder mask.

Corresponding to the above-mentioned packaging structure, a packaging method is further provided according to an embodiment of the present disclosure, which includes: providing a wafer to be packaged, where a first surface of the wafer to be packaged includes multiple chip units and cutting channel regions located between the multiple chip units, and each of the multiple chip units includes a sensing region; providing a cover substrate, where multiple support structures are formed on a first surface of the cover substrate, and the support structures correspond to the sensing regions on the wafer to be packaged; attaching the first surface of the cover substrate with the first surface of the wafer to be packaged, where cavities are formed by the support structures and the first surface of the wafer to be packaged, and the sensing regions are located in the cavities; and cutting the wafer to be packaged and the cover substrate along the cutting channel regions, to form multiple packaging structures, where each of the multiple packaging structures includes one of the multiple chip units and the upper cover plate formed by cutting the cover substrate, and the upper cover plate has a preset thickness, so that light reflected by a sidewall of the upper over plate is not directly incident on the sensing region.

Optionally, the preset thickness ranges from 50 μm to 200 μm.

Optionally, a ratio of the preset thickness to a width of the support structure may be smaller than a ratio of a height of the support structure to a width of the sensing region.

Optionally, the provided cover substrate may have the preset thickness.

Optionally, the provided cover substrate may have a thickness greater than the preset thickness, and the packaging method may further include: thinning the cover substrate, so that the thinned cover substrate has the preset thickness.

The packaging method may further include: thinning the cover substrate, so that the thinned cover substrate has the preset thickness, which ranges from 50 μm to 200 μm.

Optionally, the cutting the wafer to be packaged and the cover substrate along the cutting channel regions may include: performing a first cutting process, which includes cutting the wafer to be packaged along the cutting channel regions from a second surface of the wafer to be packaged opposite to the first surface of the wafer to be packaged until the first surface of the wafer to be packaged is reached, to form a first cutting groove; and performing a second cutting process, which includes continuing to cut the cover substrate to form a second cutting groove connected with the first cutting groove, to form multiple chip packaging structures.

Optionally, the chip unit may further include a contact pad located outside the sensing region, and after attaching the first surface of the cover substrate with the first surface of the wafer to be packaged, the packaging method may further include: thinning the wafer to be packaged from a second surface of the wafer to be packaged opposite to the first surface of the wafer to be packaged; etching the wafer to be packaged from the second surface of the wafer to be packaged, to form through holes through which the contact pads of the chip units are exposed; forming an insulation layer on the second surface of the wafer to be packaged and surfaces of side walls of the through holes; forming a metal layer on a surface of the insulation layer, where the metal layer is connected with the contact pads; forming a solder mask on a surface of the metal layer and the surface of the insulation layer, where the solder mask is provided with openings through which a portion of the surface of the metal layer is exposed; and forming protrusions for external connection on a surface of the solder mask, where the openings are filled by the protrusions for external connection.

Compared with the conventional technology, the technical solution according to the embodiments of the present disclosure has following advantages.

The packaging structure according to the embodiments of the present disclosure includes the chip unit and the upper cover plate, the first surface of the chip unit includes the sensing region, the first surface of the upper cover plate is provided with the support structure, the upper cover plate covers the first surface of the chip unit, the support structure is located between the upper cover plate and the chip unit, and the sensing region is located in the cavity enclosed by the support structure and the first surface of the chip unit. The upper cover plate has the preset thickness which is small, so that light reflected by the sidewall of the upper cover plate is not directly incident on the sensing region, thereby improving an imaging quality of the packaging structure serving as an image sensor.

Correspondingly, the packaging method according to the embodiments of the present disclosure used for forming the above-mentioned packaging structure also has the above-mentioned advantages.

### BRIEF DESCRIPTION OF THE DRAWINGS

FIG. 1 shows a cross-sectional view illustrating a structure of an image sensor chip according to the conventional technology;

FIG. 2 shows a cross-sectional view illustrating a structure of a packaging structure according to an embodiment of the present disclosure; and

FIGS. 3 to 9 show schematic structural diagrams of intermediate structures formed during implementation of a packaging method according to an embodiment of the present disclosure.

### DETAILED DESCRIPTION

From the technical background, it can be seen that an image sensor formed by the conventional technology exhibits poor performance.

The inventor of the present disclosure studies a process of packaging image sensor chips using the conventional wafer level chip size packaging technology, and finds that the image sensor chips formed using the conventional technology exhibit poor performance, since light incident on the sensing region is disturbed by an upper cover substrate formed above the sensing region during the chip packaging procedure, which reduces the imaging quality.

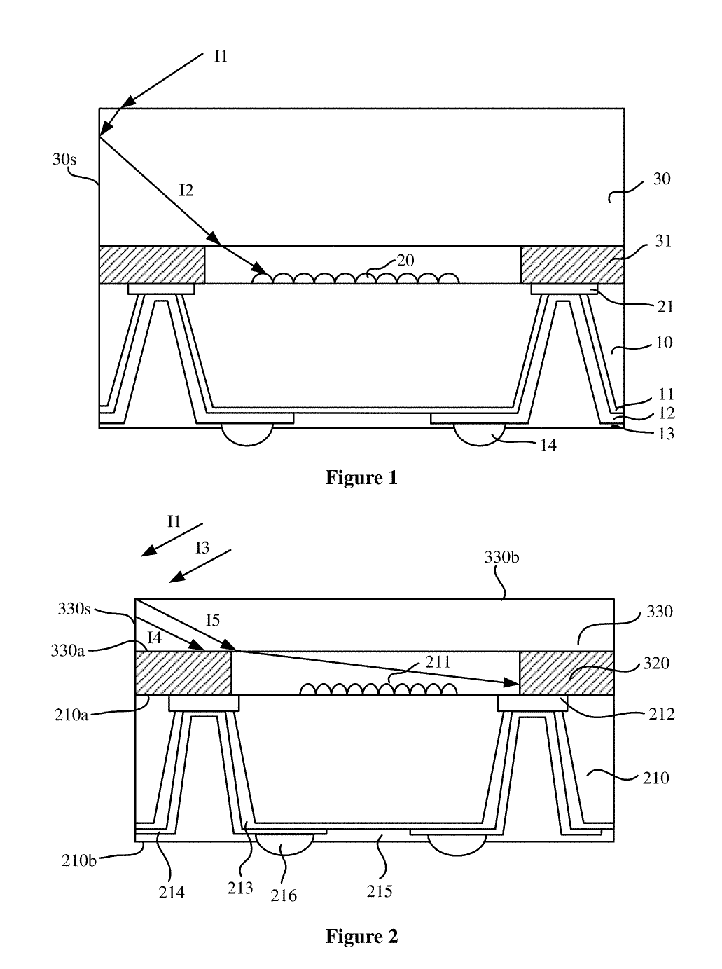

Specifically, reference is made to FIG. 1, which shows a cross-sectional view illustrating a structure of an image sensor chip formed using the conventional technology. The image sensor chip includes: a substrate 10; a sensing region 20 located on a first surface of the substrate 10; contact pads 21 located on the first surface of the substrate 10 on both sides of the sensing region 20; through holes (not indicated in FIG. 1) extending through the substrate 10 from a second surface opposite to the first surface of the substrate 10, where the contact pads 21 are exposed through the through holes; an insulation layer 11 located on side walls of the through holes and the second surface of the substrate 10; a wiring layer 12 covering the contact pads 21 and a portion of the insulation layer 11 from the second surface; a solder mask 13 covering the wiring layer 12 and the insulation layer 11, where the solder mask 13 includes openings; solder balls 14 which are located in the openings of the solder mask 13 and electrically connected with the contact pads 21 via the wiring layer 12; a cavity wall 31 located around the sensing region 20 and on the first surface of the substrate 10; and an upper cover substrate 30 located on the cavity wall. A cavity is formed by the upper cover substrate 30, the cavity wall 31, and the first surface of the substrate 10, so that the sensor 20 is located in the cavity, thereby preventing the sensing region 20 from being contaminated or damaged during packaging and use. The upper cover substrate 30 generally has a great thickness such as 400 μm.

The inventor of the present disclosure found that, during use of the above image sensor chip, when light I1 is incident on the upper cover substrate 30 of the image sensor, a portion of the light which enters the upper cover substrate 30 is incident on a side wall 30s of the upper cover substrate 30, and is refracted and reflected. If the reflected light is incident on the sensing region 20, imaging by the image sensor is disturbed. In an imaging procedure of an image sensor, the disturbance results in a virtual image formed in a direction opposite to an optical path of the reflected light I2, which causes reduction in the imaging quality.

In addition, with the trend of miniaturization of the wafer level chip size package, an increasing number of sensor chip packages are integrated on a wafer level chip, and the size of single finished chip packages is decreased, resulting in a decreased distance from the side wall of the upper cover substrate 30 to an edge of the sensing region 20. In this case, the above disturbance is more serious.

Based on the above research, a packaging structure and a packaging method for forming the packaging structure are provided according to the embodiments of the present disclosure. The packaging structure includes a chip unit and an upper cover plate. A first surface of the chip unit includes a sensing region. A first surface of the upper cover plate is provided with a support structure, the upper cover plate covers the first surface of the chip unit, the support structure is located between the upper cover plate and the chip unit, and the sensing region is located in a cavity enclosed by the support structure and the first surface of the chip unit. In the packaging structure according to the present disclosure, the upper cover plate has a preset thickness, so that light reflected by a sidewall of the upper cover plate is not directly incident on the sensing region, thereby reducing interfering light which enters the sensing region, and improving an imaging quality of the sensing region. Correspondingly, the packaging method for forming the above-mentioned packaging structure according to an embodiment of the present disclosure also has the above advantages.

To make the above object, features and advantages of the present disclosure more apparent and easier to be understood, specific embodiments of the present disclosure are illustrated in detail in conjunction with the drawings hereinafter.

It is to be noted that, the objective of providing the drawings is to help understanding embodiments of the present disclosure, and should not be construed to unduly limit the present disclosure. For the purpose of clarity, the dimensions in the drawings are not drawn to scale, and may be enlarged, reduced or changed in other manners.

First, a packaging structure is provided according to an embodiment of the present disclosure. Referring to FIG. 2, the packaging structure includes: a chip unit 210, where the chip unit 210 includes a first surface 210a and a second surface 210b opposite to the first surface 210a, and the first surface 210a includes a sensing region 211; and an upper cover plate 330, where the upper cover plate 330 includes a first surface 330a and a second surface 330b opposite to the first surface 330a, the first surface 330a is provided with a support structure 320, the upper cover plate 330 covers the first surface 210a of the chip unit 210, the support structure 320 is located between the upper cover plate 330 and the chip unit 210, and the sensing region 211 is located in a cavity enclosed by the support structure 320 and the first surface 210a of the chip unit 210. The upper cover plate 330 has a preset thickness, so that light reflected by a sidewall 330s of the upper cover plate 330 is not directly incident on the sensing region 211.

In an embodiment of the present disclosure, the preset thickness of the upper cover plate 330 ranges from 50 μm to 200 μm. For example, the preset thickness of the upper cover plate 330 is 100 μm. Since the upper cover plate 330 has a small thickness, light reflected by the sidewall 330s of the upper cover plate 330 is not directly incident on the sensing region 211. The light being directly incident on the sensing region 211 refers to that the light is not reflected by other interfaces before being incident on the sensing region 211. Specifically, the packaging structure according to an embodiment of the present disclosure is compared with the image sensor according to the conventional technology shown in FIG. 1, where the same incident light I1 is taken as an example. In FIG. 1, the light I1 enters the upper cover substrate 30 of the image sensor, is reflected by the sidewall 30s of the upper cover substrate 30 and incident on the sensing region 20, and interferes with imaging of the sensing region 20. However, as shown FIG. 2, in the packaging structure according to an embodiment of the present disclosure, the upper cover plate 330 has the preset thickness such as 100 μm, which is relatively small, so that the light I1 does not enter the upper cover plate 330, and is not reflected by the sidewall 330s of the upper cover plate 330, thus interference to the sensing region 211 can be avoided.

In some embodiments, the preset thickness of the upper cover plate 330 is determined based on a width of the sensing region 330, as well as a width and a height of the support structure 320. Specifically, with continuing reference to FIG. 2, it is assumed that light I3 is incident on the upper cover plate 330 and reflected by the sidewall 330s. In some situations, the light reflected by the sidewall 330s of the upper cover plate 330, which is denoted by I4, is incident on a top surface of the support structure 320. Therefore, whether the reflected light I4 is to directly incident on the sensing region 211 is related to the width of the support structure 320. In some other situations, the light reflected by the sidewall 330s of the upper cover plate 330, which is denoted by I5, enters the cavity where the sensing region 211 is located, passes over the sensing region 211, and is incident on the support structure 320 on the other side. Therefore, whether the reflected light I5 is to directly incident on the sensing region 211 is further related to the height of the support structure 320 and the width of the sensing region 211, namely, to a shape of the cavity in which the sensing region 211 is located. In summary, according to an embodiment of the present disclosure, the preset thickness of the upper cover plate 330 is determined based on the width of the sensing region 211, as well as the width and the height of the support structure 320, so that the light reflected by the sidewall 330s of the upper cover plate 330 is not directly incident on the sensing region 211. For example, a ratio of the preset thickness of the cover plate to the width of the support structure is set to be smaller than a ratio of the height of the support structure to the width of the sensing region.

In some other embodiments, the preset thickness of the upper cover plate 330 is determined based on a further consideration of factors such as a distance between the sensing region 211 and an inner sidewall of the support structure 320, and a refractive index of the upper cover platy 330. To summarize, the preset thickness of the upper cover plate 330 is determined so that light reflected by the sidewall 330s of the upper cover plate 330 is not directly incident on the sensing region 211.

In this embodiment, the packaging structure further includes: a contact pad 212 located outside the sensing region 211; a through hole (not indicated) extending through the chip unit 210 from the second surface 210b of the chip unit 210 opposite to the first surface 210a of the chip unit 210, where the contact pad 212 is exposed through the through hole; an insulation layer 213 covering the second surface 210b of the chip unit 210 and a surface of a sidewall of the through hole; a metal layer 214 located on a surface of the insulation layer 213 and electrically connected to the contact pad 212; a solder mask 215 located on a surface of the metal layer 214 and the surface of the insulation layer 213, where the solder mask 215 includes an opening (not indicated) through which a portion of the metal layer 214 is exposed; and a protrusion 216 for external connection by which the opening is filled, where the protrusion 216 for external connection is exposed outside a surface of the soldering mask 215. In the above-mentioned structure, the sensing region 211 is electrically connected to an external circuit via the contact pad 212, the metal layer 214, and the protrusion 216 for external connection, thereby transmitting electrical signals.

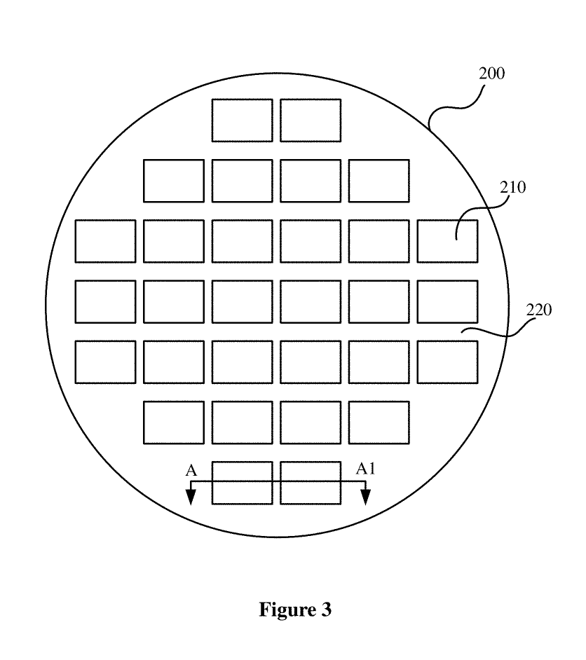

Correspondingly, a packaging method for forming the packaging structure shown in FIG. 2 is provided according to an embodiment of the present disclosure. Reference is made to FIGS. 3 to 9, which are schematic diagrams showing intermediate structures formed in a packaging process using the packaging method according to an embodiment of the present disclosure.

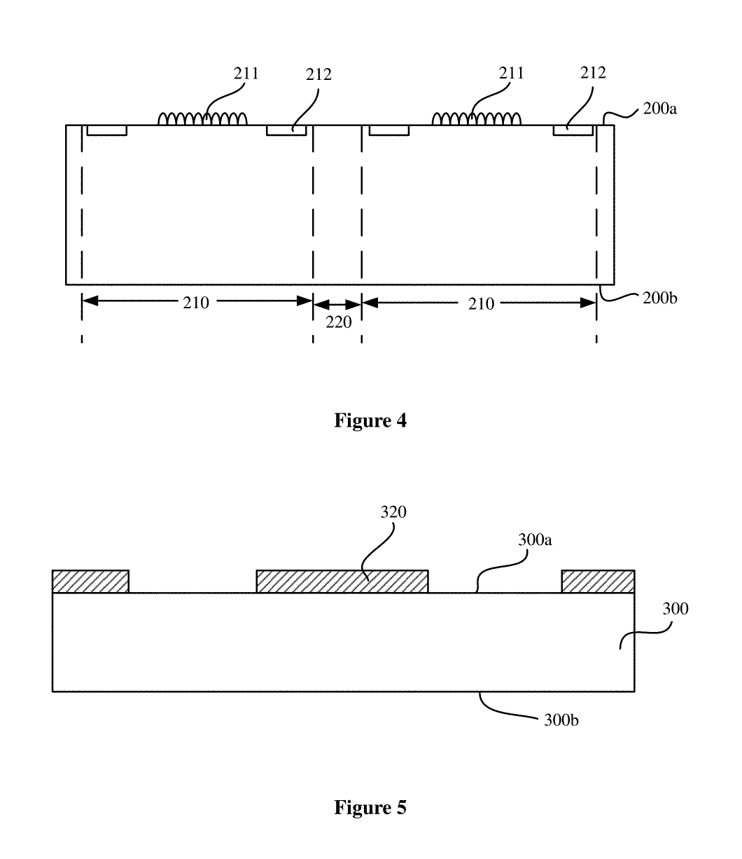

First, referring to FIGS. 3 and 4, a wafer to be packaged 200 is provided. FIG. 3 is a plane view showing a structure of the wafer to be packaged 200. FIG. 4 is a section view taken along AA1 in FIG. 3.

The wafer to be packaged 200 includes a first surface 200a and a second surface 200b opposite to the first surface 200a. The first surface 200a of the wafer to be packaged 200 is provided with multiple chip units 210 and cutting channel regions 220 located between the chip units 210.

In this embodiment, the multiple chip units 210 on the wafer to be packaged 200 are arranged in an array, and the cutting channel regions 220 are located between adjacent chip units 210. The wafer to be packaged 200 is subsequently cut along the cutting channel regions 220, to form multiple chip packaging structures, each of which includes the chip unit 210.

In this embodiment, the chip unit 210 is an image sensor chip unit, and includes a sensing region 211 and a contact pad 212 located outside the sensing regions 211. The sensing region 211 is an optical sensing region, and may be formed, for example, by multiple photodiodes arranged in an array, where the photodiode can convert an optical signal incident on the sensing region 211 into an electrical signal. The contact pad 212 serves as an input terminal and an output terminal through which a component in the sensing region 211 is connected to an external circuit. In some embodiments, the chip unit 210 is formed on a silicon substrate, and further includes other functional components formed within the silicon substrate.

It should be noted that, for clearance, only the section view of the wafer to be packaged 200 taken along AA1 as shown in FIG. 3 is taken as an example for illustration in subsequent steps of the packaging method according to the embodiment of the present disclosure, and similar process steps are performed in other regions.

Next, referring to FIG. 5, a cover substrate 300 is provided. The cover substrate 300 includes a first surface 300a and a second surface 300b opposite to the first surface 300a. Multiple support structures 320 are formed on the first surface 300a of the cover substrate 300. Groove structures formed by the support structures 320 and the first surface 300a correspond to the sensing regions 211 on the wafer to be packaged 200.

In this embodiment, the cover substrate 300 covers the first surface 200a of the wafer to be packaged 200 in subsequent processes for protecting the sensing regions 211 on the wafer to be packaged 200. Light needs to pass through the cover substrate 300 before reaching the sensing regions 211. Therefore, the cover substrate 300 is made of a transparent material which has high transparency. Both surfaces 300a and 300b of the cover substrate 300 are flat and smooth, and do not cause scattering and diffuse reflection of incident light. Specifically, a material of the cover substrate 300 may be inorganic glass, organic glass or other transparent materials with certain strength.

In some embodiments, the support structures 320 are formed by depositing a support structure material layer on the first surface 300a of the cover substrate 300 and etching the support structure material layer. Specifically, the support structure material layer (not shown) covering the first surface 300a of the cover substrate 300 is first formed, then the support structure material layer is patterned, and a part of the support structure material layer is removed to form the support structures 320. Positions of the groove structures formed by the support structures 320 and the first surface 300a on the cover substrate 300 correspond to positions of the sensing regions 211 on the wafer to be packaged 200, so that the sensing regions 211 can be located in the grooves and between the support structures 320 after a subsequent attaching process is performed. In some embodiments, the support structure material layer is made of wet film photoresist or dry film photoresist, and is formed by a spraying process, a spin coating process, an adhesion process or the like. The support structures 320 are formed by patterning the support structure material layer through exposure and development. In some embodiments, the support structure material layer may also be formed with an insulating dielectric material such as silicon oxide, silicon nitride, and silicon oxynitride, by a deposition process, and is subsequently patterned using a photolithographic process and an etching process to form the support structures 320.

In some other embodiments, the support structures 320 may also be formed by etching the cover substrate 300. Specifically, a patterned photoresist layer may be formed on the cover substrate 300. Then, the cover substrate 300 is etched with the patterned photoresist layer as a mask, to form the support structures 320 in the cover substrate 300. The support structures 320 are raised portions on the first surface 300a of the cover substrate 320.

In an embodiment of the present disclosure, the cover substrate 300 has a preset thickness. After the cover substrate is subsequently cut to form upper cover plates of packaging structures, the upper cover plates also have the preset thickness, so that light reflected by the sidewalls of the upper cover plates is not directly incident on the sensing regions 211 of the chip units. In some embodiments, the preset thickness may range from 50 μm to 200 μm, and may be 100 μm, for example.

In some embodiments, the cover substrate 300 with the preset thickness is directly provided, then the support structures 320 are formed on the cover substrate 300, and the cover substrate 300 is attached with the wafer to be packaged 200. In some other embodiments, a cover substrate 300 with a thickness greater than the preset thickness is provided. After the support structures 320 are formed on the first surface 300a of the cover substrate 300, the cover substrate 300 is thinned to the preset thickness from the second surface 300b. The cover substrate 300 with a greater thickness can provide a stronger mechanical support during the process of forming the support structures 320, thereby preventing damages. In some other embodiments, the cover substrate 300 with the thickness greater than the preset thickness is provided. After the support structures 320 are formed on the cover substrate 300 and the cover substrate 320 is attached with the wafer to be packaged 200, the cover substrate 300 is thinned to the preset thickness from the second surface 300b of the cover substrate. Similarly, the cover substrate 300 with a greater thickness can provide a stronger mechanical support during subsequent processes. The above-mentioned thinning process may be a masking process, an etching process, or the like, which is not limited herein.

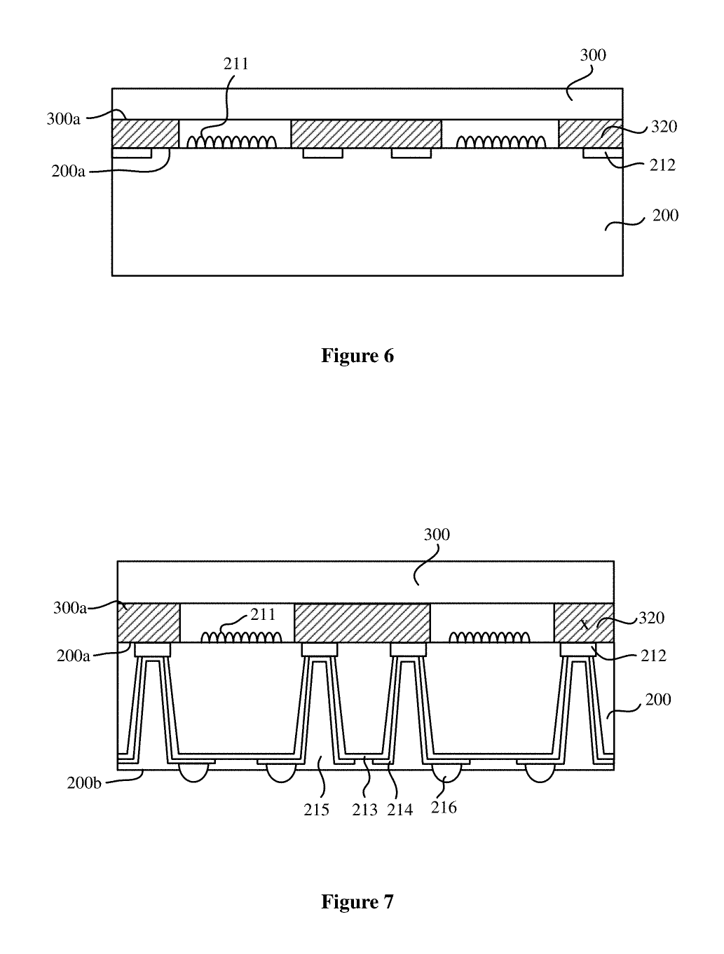

Next, reference is made to FIG. 6. The first surface 300a of the cover substrate 300 is attached with the first surface 200a of the wafer to be packaged 200. The support structure 320 is located between the first surface 300a of the cover substrate 300 and the first surface 200a of the wafer to be packaged 200, so that cavities (not indicated) are formed by the support structures 320 and the first surface 200a of the wafer to be packaged 200, and the sensing regions 211 are located in the cavities.

In this embodiment, the cover substrate 300 is attached with the wafer to be packaged 200 through an adhesive layer (not shown). For example, the adhesive layer may be formed on top surfaces of the support structures 320 on the first surface 300a of the cover substrate 300, and/or on the first surface 200a of the wafer to be packaged 200 by a spraying process, a spin coating process, or an adhesion process. Then, the first surface 300a of the cover substrate 300 is attached with the first surface 200a of the wafer to be packaged 200 through the adhesive layer. The adhesive layer performs an adhesive function, an insulation function and a sealing function. The adhesive layer may be made of a polymeric adhesive material, such as silica gel, epoxy resin, benzocyclobutene and other polymeric materials.

In this embodiment, after the first surface 300a of the cover substrate 300 is attached with the first surface 200a of the wafer to be packaged 200, the support structures 320 and the first surface 200a of the wafer to be packaged 200 form the cavities. Positions of the cavities correspond to positions of the sensing regions 211, and an area of the cavity is slightly greater than an area of the sensing region 211, so that the sensing region 211 is located in the cavity. In this embodiment, after the cover substrate 300 is attached with the wafer to be packaged 200, the contact pads 212 on the wafer to be packaged 200 are covered by the support structures 320 on the cover substrate 300. The cover substrate 300 can protect the wafer to be packaged 200 in subsequent processes.

Next, reference is made to FIG. 6. The wafer to be packaged 200 is packaged.

First, the wafer to be packaged 200 is thinned from the second surface 200b of the wafer to be packaged 200 to facilitate subsequent etching for forming the through holes. The wafer to be packaged 200 may be thinned by a mechanical polishing process, a chemical mechanical polishing process, or the like. Then, the wafer to be packaged 200 is etched from the second surface 200b of the wafer to be packaged 200 to form through holes (not indicated), where the contact pads 212 on a side of the first surface 200a of the wafer to be packaged 200 are exposed through the through holes. Next, an insulation layer 213 is formed on the second surface 200b of the wafer to be packaged 200 and side walls of the through holes, where the contact pads 212 at bottoms of the through holes are exposed through the insulation layer 213. The insulation layer 213 can provide electrical insulation for the second surface 200b of the wafer to be packaged 200, and can provide electrical insulation for a substrate of the wafer to be packaged 200 exposed through the through holes. A material of the insulation layer 213 may be silicon oxide, silicon nitride, silicon oxynitride or insulating resin. Then, a metal layer 214 connected with the contact pads 212 is formed on a surface of the insulation layer 213. The metal layer 214 may be used as a redistribution layer with which the contact pads 212 are extended to the second surface 200b of the wafer to be packaged 200 for connection to an external circuit. The metal layer 214 is formed by depositing and etching a metal thin film. Next, a solder mask 215 with openings (not indicated) is formed on a surface of the metal layer 214 and the surface of the insulation layer 213, where a portion of the surface of the metal layer 214 is exposed through the openings. A material of the solder mask 215 is an insulating dielectric material such as silicon oxide and silicon nitride. The solder mask 215 functions to protect the metal layer 214. Then, protrusions 216 for external connection are formed on a surface of the solder mask 215, where the openings are filled by the protrusions 216 for external connection. The protrusion 216 for external connection may be a connection structure such as a solder ball and a metal pillar, and may be made of a metal material such as copper, aluminum, gold, tin, and lead.

After the wafer to be packaged 200 is packaged, the chip packaging structure obtained by a subsequent cutting process can be connected with an external circuit through the protrusion 216 for external connection. After an optical signal is converted by the sensing region 211 of the chip unit into an electrical signal, the electrical signal sequentially passes through the contact pad 212, the metal layer 214 and the protrusion 216 for external connection and is transmitted to the external circuit for processing.

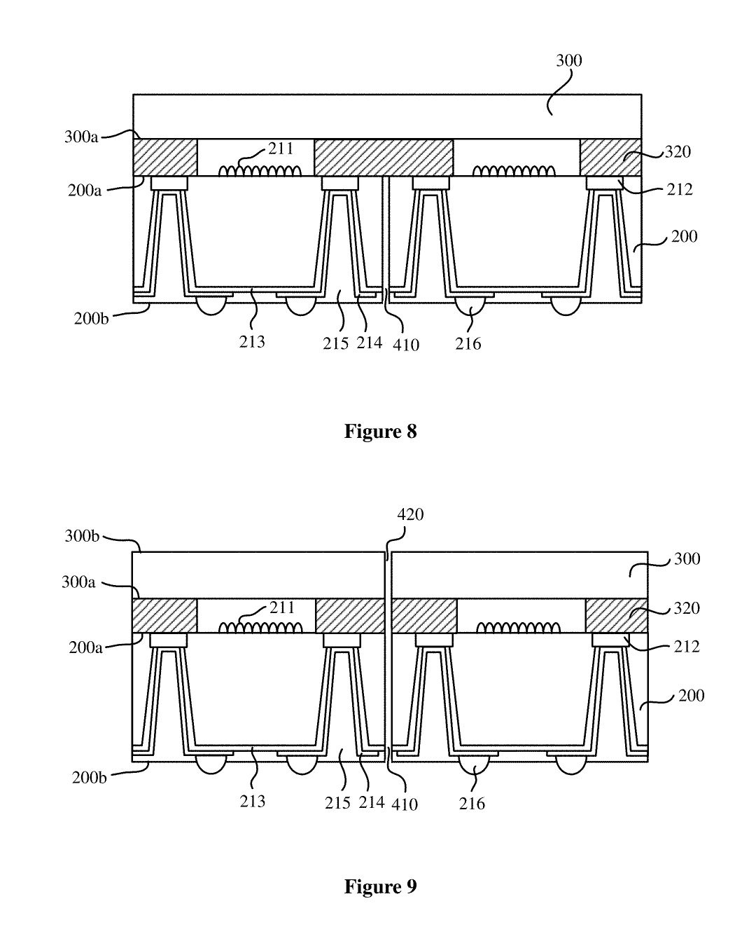

Next, reference is made to FIGS. 8 and 9, the wafer to be packaged 200 and the cover substrate 300 are cut along the cutting channel regions 220 (referring to FIG. 4), to form multiple packaging structures as shown in FIG. 2. Each of the packaging structures includes the chip unit 210 and the upper cover plate 330 located on the chip unit 210 and formed by cutting the cover substrate 300. The upper cover plate 330 has the preset thickness, so that light reflected by the side wall 330s of the upper cover plate 330 is not directly incident on the sensing region.

In this embodiment, the cutting performed on the wafer to be packaged 200 and the cover substrate 300 includes a first cutting process and a second cutting process. Specifically, as shown in FIG. 8, first, the first cutting process is performed, where the wafer to be packaged 200 is cut along the cutting channel regions 220 shown in FIG. 4 from the second surface 200b of the wafer to be packaged 200 until the first surface 200a of the wafer to be packaged 200 is reached to form a first cutting groove 410. Slicing knife cutting or laser cutting may be used in the first cutting process, where the slicing knife cutting may be performed using a metal knife or a resin knife.

Next, referring to FIG. 9, the second cutting process is performed, where the cover substrate 300 is cut from the second surface 300b of the cover substrate 300, along regions corresponding to the cutting channel regions 220 shown in FIG. 4, until the first surface 200a of the wafer to be packaged 200 is reached, to form a second cutting groove 420 connected with the first cutting groove 410, and form the multiple packaging structures, by which the cutting process is finished. Slicing knife cutting or laser cutting may be used in the second cutting process.

In some other embodiments, the second cutting process may include continuing to cut the cover substrate 300 from the first surface 300a of the cover substrate 300 along the first cutting groove 410, to form the second cutting groove 420 extending through the cover substrate 300, by which the cutting process is finished.

It should be noted that the first cutting process may be performed after the second cutting process in some other embodiments, and the wafer to be packaged 200 and the cover substrate 300 may be cut by only one cutting process in some other embodiments, which are not limited herein.

One can refer to the description of the packaging structure shown in FIG. 2 for description of the packaging structure formed by the packaging method according to the embodiment of the present disclosure, which is not described here.

The present disclosure is disclosed above, but is not limited thereto. Various alternations and modifications can be made to the technical solutions of the present disclosure by those skilled in the art without deviation from the spirit and scope of the present disclosure. Therefore, the scope of protection of the present disclosure is defined by the appended claims.

1. A packaging structure, comprising:
a chip unit, wherein a first surface of the chip unit comprises a sensing region; and
an upper cover plate, wherein
a first surface of the upper cover plate is provided with a support structure,
the upper cover plate covers the first surface of the chip unit,
the support structure is located between the upper cover plate and the chip unit,
the sensing region is located in a cavity enclosed by the support structure and the first surface of the chip unit, and
the upper cover plate has a preset thickness, so that light reflected by a sidewall of the upper cover plate is not directly incident on the sensing region.

2. The packaging structure according to claim 1, wherein the preset thickness ranges from 50 μm to 200 μm.

3. The packaging structure according to claim 2, wherein the preset thickness is 100 μm.

4. The packaging structure according to claim 1, wherein the preset thickness is determined based on a width of the sensing region, a width of the support structure, and a height of the support structure.

5. The packaging structure according to claim 4, wherein a ratio of the preset thickness to the width of the support structure is smaller than a ratio of the height of the support structure to the width of the sensing region.

6. The packaging structure according to claim 1, wherein a material of the upper cover plate is a transparent material.

7. The packaging structure according to claim 1, wherein the chip unit further comprises:
a contact pad located outside the sensing region;
a through hole extending through the chip unit from a second surface of the chip unit opposite to the first surface of the chip unit, wherein the contact pad is exposed through the through hole;
an insulation layer covering the second surface of the chip unit and a surface of a sidewall of the through hole;
a metal layer located on a surface of the insulation layer and electrically connected to the contact pad;
a solder mask located on a surface of the metal layer and the surface of the insulation layer, wherein the solder mask is provided with an opening through which a portion of the metal layer is exposed; and
a protrusion for external connection by which the opening is filled, wherein the protrusion for external connection is exposed outside a surface of the solder mask.

8. A packaging method for forming a packaging structure, comprising:
providing a wafer to be packaged, wherein a first surface of the wafer to be packaged comprises a plurality of chip units and cutting channel regions located between the plurality of chip units, and each of the plurality of chip units comprises a sensing region;
providing a cover substrate, wherein a plurality of support structures are formed on a first surface of the cover substrate, and the support structures correspond to the sensing regions on the wafer to be packaged;
attaching the first surface of the cover substrate with the first surface of the wafer to be packaged, wherein cavities are formed by the support structures and the first surface of the wafer to be packaged, and the sensing regions are located in the cavities; and
cutting the wafer to be packaged and the cover substrate along the cutting channel regions, to form a plurality of packaging structures, wherein each of the plurality of packaging structures comprises one of the plurality of chip units and an upper cover plate formed by cutting the cover substrate, and the upper cover plate has a preset thickness, so that light reflected by a sidewall of the upper over plate is not directly incident on the sensing region.

9. The packaging method according to claim 8, wherein the preset thickness ranges from 50 μm to 200 μm.

10. The packaging method according to claim 8, wherein a ratio of the preset thickness to a width of the support structure is smaller than a ratio of a height of the support structure to a width of the sensing region.

11. The packaging method according to claim 8, wherein the provided cover substrate has the preset thickness.

12. The packaging method according to claim 8, wherein the provided cover substrate has a thickness greater than the preset thickness, and the packaging method further comprises: thinning the cover substrate, so that the thinned cover substrate has the preset thickness.

13. The packaging method according to claim 8, wherein the cutting the wafer to be packaged and the cover substrate along the cutting channel regions comprises:
performing a first cutting process, which comprises cutting the wafer to be packaged along the cutting channel regions from a second surface of the wafer to be packaged opposite to the first surface of the wafer to be packaged until the first surface of the wafer to be packaged is reached, to form a first cutting groove; and
performing a second cutting process, which comprises cutting the cover substrate to form a second cutting groove connected with the first cutting groove, to form a plurality of chip packaging structures.

14. The packaging method according to claim 8, wherein the chip unit further comprises a contact pad located outside the sensing region, and after attaching the first surface of the cover substrate with the first surface of the wafer to be packaged, the packaging method further comprises:
thinning the wafer to be packaged from a second surface of the wafer to be packaged opposite to the first surface of the wafer to be packaged;
etching the wafer to be packaged from the second surface of the wafer to be packaged, to form through holes through which the contact pads of the chip units are exposed;
forming an insulation layer on the second surface of the wafer to be packaged and surfaces of side walls of the through holes;
forming a metal layer on a surface of the insulation layer, wherein the metal layer is connected with the contact pads;
forming a solder mask on a surface of the metal layer and the surface of the insulation layer, wherein the solder mask is provided with openings through which a portion of the surface of the metal layer is exposed; and
forming protrusions for external connection on a surface of the solder mask, wherein the openings are filled by the protrusions for external connection.
